(19) United States
(12) Patent Application Publication
(10) Pub. No.: US 2004/0152242 A1
(43) Pub. Date: Aug. 5, 2004

(54) Device package utilizing interconnect strips to make connections between package and die

(76) Inventor: Chun Kit Wong, Taman Brown (MY)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/356,234

(22) Filed: Jan. 30, 2003

(51) Int. Cl. H01L 23/495; H01L 21/44

(52) U.S. Cl. 438/125; 257/673; 438/106; 438/122

(57) ABSTRACT

A circuit having a die mounted in a package utilizing a novel interconnect structure is disclosed. The die has an integrated circuit and a plurality of chip connection pads. The package has a plurality of package connection pads for connecting the die to circuitry that is external to the package, one such package connection pad corresponding to each of the chip connection pads. The circuit utilizes a plurality of flat conducting interconnect strips to connect the chip connection pads to the die connection pads. Each interconnect strip has a first end that is bonded to one of the chip connection pads and a second end bonded to the package interconnect pad corresponding to that chip connection pad. The interconnect strips are preferably constructed from copper and are preferably bonded to the connection pads by a conductive adhesive.

### FIELD OF THE INVENTION

The present invention relates to packaging for semiconductor chips and the like.

### BACKGROUND OF THE INVENTION

Microelectronic components are typically fabricated on wafers that are then divided into individual dies that are separately packaged to form the integrated circuits that are connected to printed circuit boards and the like. The package includes the interconnect pins or connection points utilized for connecting the circuitry on the die to the various conductors on the printed circuit board. Within the package, the interconnect pins are typically connected to corresponding connections on the die by gold wires using a wire bonding apparatus that connects each pad on the die to a corresponding pad on the package, one wire at a time. This connection technique requires that the wires form loops having one end on the die and one end on a connection pad in the package. The loop extends above the surface of the die by a significant amount. Accordingly, a significant vertical space must be allocated for the wire loops. This vertical space substantially increases the height of the finished package. In many applications package height is critical.

In addition, the wires must be applied one at a time. As the complexity of the packaged circuits increases, the number of connections per packaged circuit also increases. The time needed to perform this bonding can significantly decrease the assembly throughput for circuits having a large number of connections between the die and the package.

### SUMMARY OF THE INVENTION

The present invention includes a circuit having a die mounted in a package. The die has an integrated circuit and a plurality of chip connection pads. The package has a plurality of package connection pads for connecting the die to circuitry that is external to the package, one such package connection pad corresponding to each of the chip connection pads. The circuit utilizes a plurality of flat conducting interconnect strips to connect the chip connection pads to the die connection pads. Each interconnect strip has a first end that is bonded to one of the chip connection pads and a second end bonded to the package interconnect pad corresponding to that chip connection pad. The interconnect strips are preferably constructed from copper and are preferably bonded to the connection pads by a conductive adhesive.

### BRIEF DESCRIPTION OF THE DRAWINGS

FIGS. 1 and 2 illustrate a typical prior art packaging scheme.

FIG. 3 is a top view of a packaged die 31 according to one embodiment of the present invention.

FIG. 4 is a cross-sectional view of packaged die 31 through line 33-33′.

FIG. 5 is a top view of the copper strips prior to being applied to the die and package.

FIG. 6 is a cross-sectional view of a die 70 after the copper strips 61 have been applied.

### DETAILED DESCRIPTION OF THE PREFERRED EMBODIMENTS OF THE INVENTION

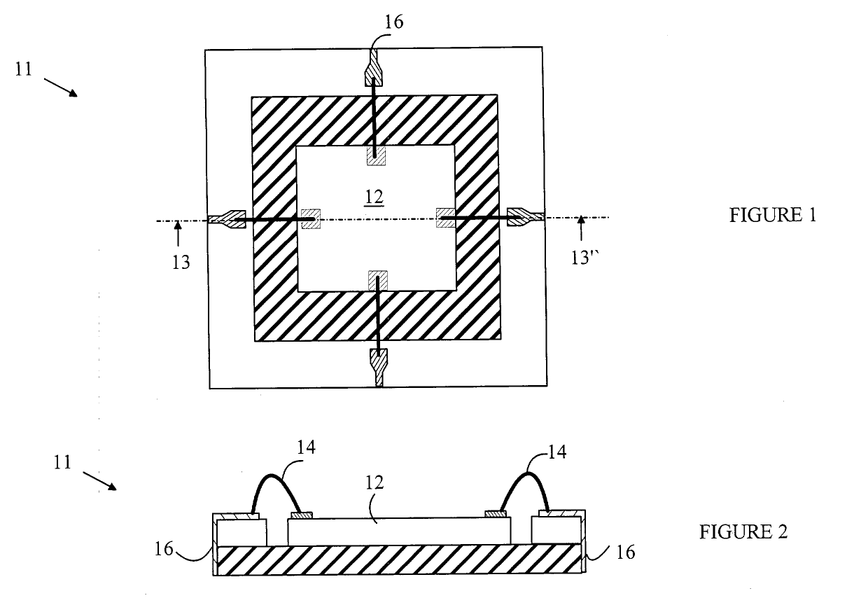

The manner in which the present invention provides its advantages can be more easily understood with reference to FIGS. 1 and 2, which illustrate a typical prior art packaging scheme. FIG. 1 is a simplified top view of a die 12 in a package 11 prior to the application of the cover to the package. FIG. 2 is a cross-sectional view through line 13-13′. The package base 15 is typically made from an epoxy. The package includes a number of pins 16 that provide electrical connections between the package and a device to which the package is connected such as a printed circuit board. The die is connected to the pins via gold wires 14. The wires are welded onto pads on the package and die and must have a loop like structure. The package typically includes a lid, which is connected to the bottom section of the package by a solder joint that provides a hermetic seal to protect the die. A space must be allocated between the die and the lid to accommodate the wire loops. This space increases the height of the die, and hence, is objectionable. To simplify the drawings, the lid has been omitted. In addition, only 4 pins are shown; however, it is to be understood that the number of pins depends on the specific circuit on the chip and may vary widely from the 4-pin design shown in the drawings.

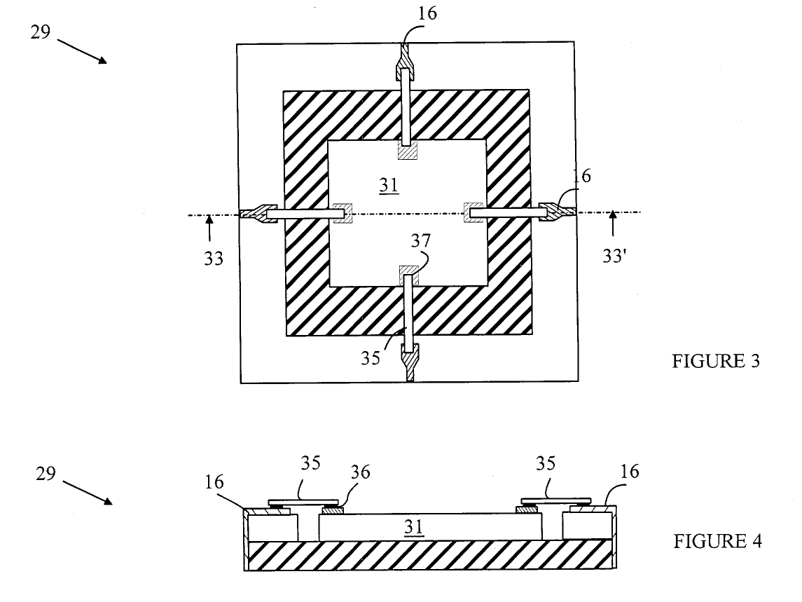

The present invention avoids the problems associated with the gold wire loops described above by replacing the gold wires with interconnect strips. Refer now to FIGS. 3 and 4, which illustrate a packaged die 29 according to one embodiment of the present invention. FIG. 3 is a top view of a packaged die 29. FIG. 4 is a cross-sectional view through line 33-33′. In the present invention, the connections between the die and the package are made via thin copper interconnect strips 35 that are connected between the die signal pads shown at 37 and the package connection pads 16 via a conducting epoxy layer 36.

Since the strips are flat and do not require the loop structure, the height of the strips over the die is substantially less than the height of the gold wire loops utilized in prior art packaging schemes. For example, the gold wires discussed above typically extend vertically to a height of 0.152 mm over the die. The copper strips of the present invention require only 0.051 mm.

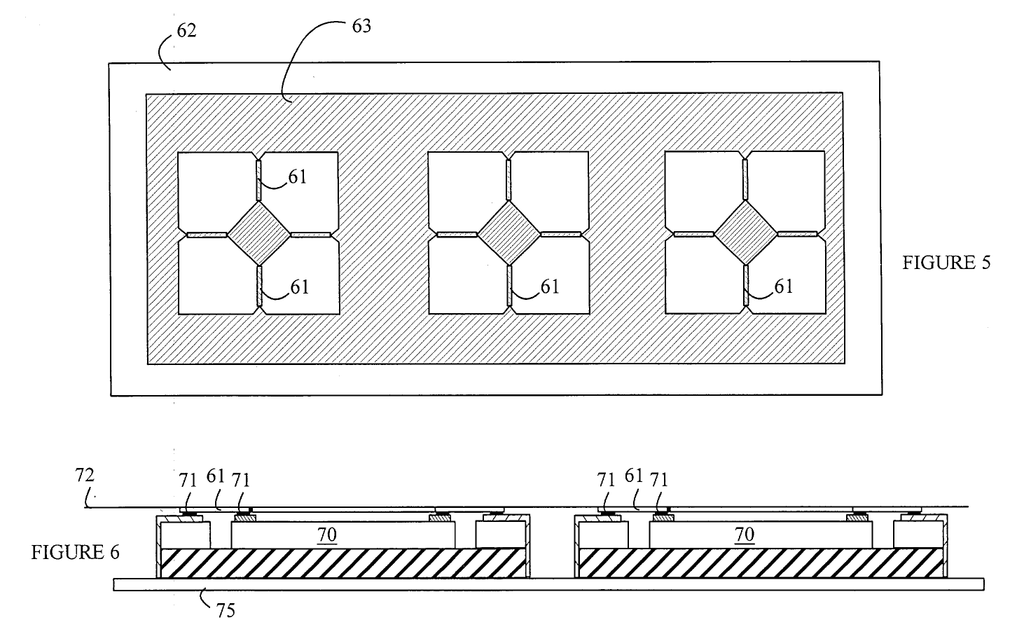

The manner in which the copper interconnect strips are applied will now be discussed in more detail with reference to FIG. 5, which is a top view of the copper strips prior to being applied to a plurality of the die and package pairs. The copper strips 61 are formed by etching a copper layer 63 that has been deposited on a Kapton tape 62. The strips for a plurality of packages are etched on a single piece of Kapton tape so that the connections for a number of packages can be applied simultaneously. In the example shown in the figure, the connection strips for three packages are shown on a single piece of tape. However, it is to be understood that the number of packages that can be processed with one strip can be much larger than this.

Refer now to FIG. 6, which is a cross-sectional view of a plurality of dies 70 after the copper strips 61 have been applied, but prior to the removal of the tape. To simplify the drawing, only two packaged dies are shown; however, it is to be understood that the number of packages that are processed simultaneously can be much larger than 2. After each die is attached to the corresponding package, the dies are placed on a carrier 75 so that all of the packaged dies can be handled together in a single “gang”. The bonding pads at the packages and at the dies are dotted with conductive pastes to create connection points 71. The preferred conductive paste is silver epoxy. However, any conductive adhesive that will bond to the copper pads can be utilized.

Next, a sheet 72 of etched copper interconnect strips is precisely placed on top of the conductive pastes such that the tie strips on the sheet are positioned over corresponding pairs of die and package pads. Sheet 72 extends over a plurality of packages that are affixed to carrier 75. A weight is then placed on sheet 72 such that the interconnect strips are forced against the corresponding connection pads. The carrier is then moved to an oven to cure the conductive adhesive. To simplify the drawing, the weight has been omitted from FIG. 6.

After the conducting adhesive has cured, the tape is torn off away from the bonded conducting strips leaving the bonded conducting strips between package and die connection pads. Finally, a cap is placed over the package and sealed in place to protect the die. The individual packages are then removed from the carrier.

In addition to reducing the height of the packaged die, the present invention also replaces the gold wires used in the prior art packaging schemes with copper strips that are considerably less expensive. Finally, the interconnections for a large number of packages can be made simultaneously with the present invention thereby reducing the time needed to assemble the parts.

The above-described embodiments of the present invention utilize copper interconnect strips. However, other metals could be utilized. Any conductor that can be etched on a packing strip can, in principle, be used provided a suitable conducting adhesive is available for bonding the conductor to the pads on the die and chip.

Various modifications to the present invention will become apparent to those skilled in the art from the foregoing description and accompanying drawings. Accordingly, the present invention is to be limited solely by the scope of the following claims.

What is claimed is:

1. A circuit comprising:
a die having an integrated circuit and a plurality of chip connection pads;
a package having a plurality of package connection pads for connecting said die to circuitry that is external to said package, one such package connection pad corresponding to each of said chip connection pads; and
a plurality of flat conducting interconnect strips, each interconnect strip having a first end that is bonded to one of said chip connection pads and a second end bonded to said package interconnect pad corresponding to that chip connection pad.

2. The circuit of claim 1 wherein said conducting interconnect strips comprise copper.

3. The circuit of claim 1 wherein said conducting interconnect strips are bonded to said chip connection pads by a conducting adhesive.

4. A method for packaging a die having a plurality of chip connection pads in a package having a plurality of package connection pads, said method comprising:
providing a sheet having a plurality of conducting interconnect strips thereon;
bonding said die in said package;
applying a conducting adhesive to said chip connection pads and said package connection pads;
applying said sheet such that one of said conducting interconnect strips connects one of said chip connection pads and one of said package connection pads; and
removing said sheet, leaving said one of said conducting interconnect strips bonded to said one of said chip connection pads and said one of said package connection pads.

5. The method of claim 4 wherein said conducting interconnect strips comprise copper.
